(19) United States
(12) Patent Application Publication
(10) Pub. No.: US 2025/0142990 A1
(43) Pub. Date: May 1, 2025

(54) IMAGE SENSOR AND METHOD OF MANUFACTURING IMAGE SENSOR

(71) Applicant: Taiwan Semiconductor Manufacturing Company, Ltd., Hsinchu (TW)

(72) Inventors: Chung-Lei Chen, Hsinchu (TW); Yen-Liang Lin, Tainan City (TW); Ru-Shang Hsiao, Jhubei City (TW)

(21) Appl. No.: 18/444,896

(22) Filed: Feb. 19, 2024

Related U.S. Application Data
(60) Provisional application No. 63/594,080, filed on Oct. 30, 2023.

(51) Int. Cl. H01L 27/146

(52) U.S. Cl. CPC H10F 39/80373; H10F 39/014

(57) ABSTRACT

The present disclosure provides an image sensor and a method of manufacturing the same. The image sensor includes a substrate and a gate electrode. The gate electrode is disposed proximate to a first side of the substrate. The gate electrode includes a first gate portion, a second gate portion, and a third gate portion. The first gate portion is disposed over the first side of the substrate. The second gate portion is disposed within the substrate and connected to the first gate portion. The third gate portion is disposed below and connected to the second gate portion. A first width of the first gate portion is greater than a second width of the second gate portion, and a third width of the third gate portion is greater than the second width.

### CROSS-REFERENCE TO RELATED APPLICATIONS

This application claims the benefit of U.S. Provisional Application No. 63/594,080, filed on Oct. 30, 2023, the contents of which are hereby incorporated by reference in their entirety.

### BACKGROUND

Complimentary Metal-Oxide Semiconductor (CMOS) image sensors can be designed with a buried photodiode region to increase the full well capacity. A more efficient mechanism to transfer the charges from the photodiode region is desirable.

### BRIEF DESCRIPTION OF THE DRA WINGS

Aspects of the present disclosure are best understood from the following detailed description when read with the accompanying figures. It is emphasized that, in accordance with standard practice in the industry, various features are not drawn to scale. In fact, the dimensions of the various features may be arbitrarily increased or reduced for clarity of discussion.

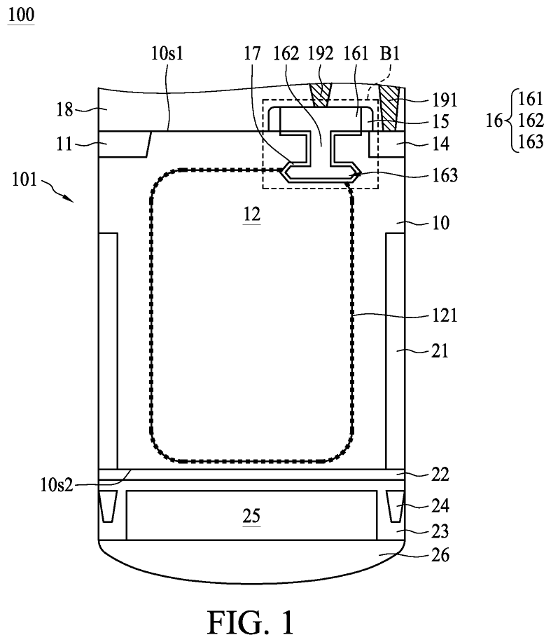

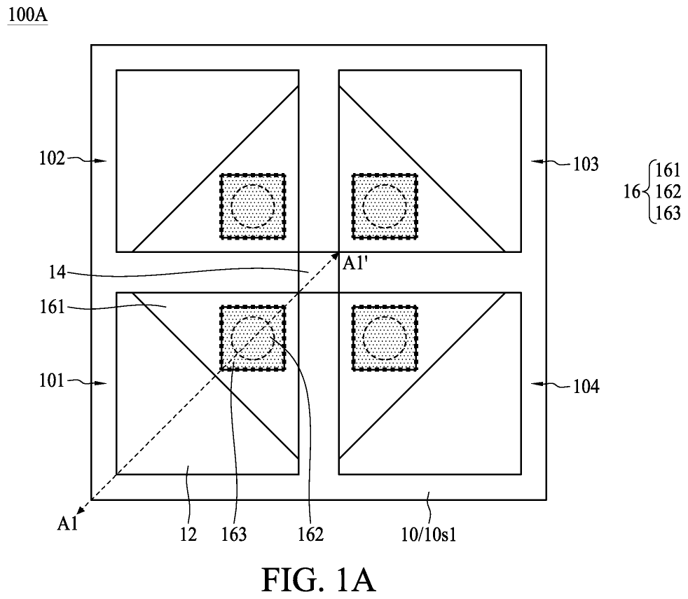

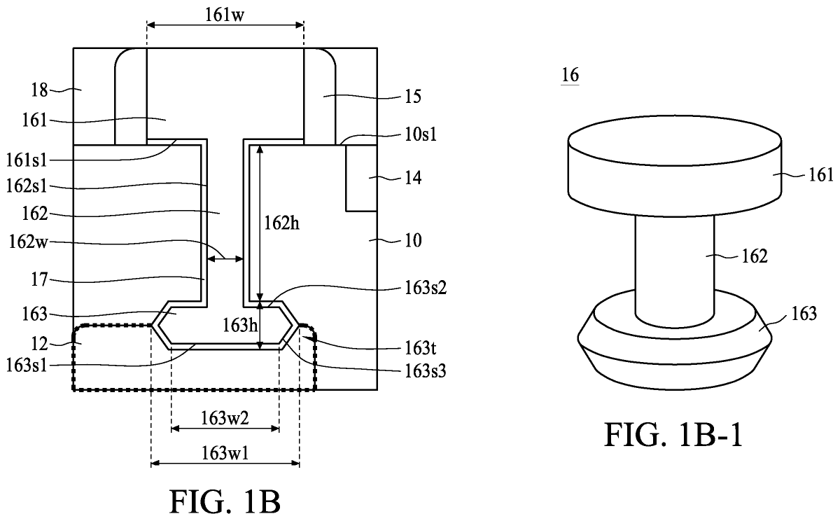

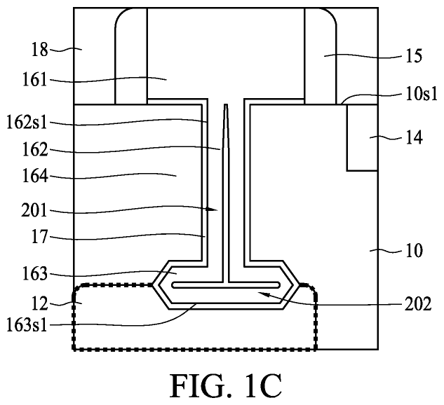

FIG. 1 illustrates a schematic diagram of a cross-sectional view of an image sensor, in accordance with some embodiments.

FIG. 1A illustrates a schematic diagram of a top view of an image sensor, in accordance with some embodiments.

FIG. 1B illustrates a schematic diagram of an enlarged view of a box B1 in FIG. 1.

FIG. 1B-1 illustrates a schematic diagram of a three-dimensional view of a gate electrode, in accordance with some embodiments.

FIG. 1C illustrates a schematic diagram of another enlarged view of a box B1 in FIG. 1.

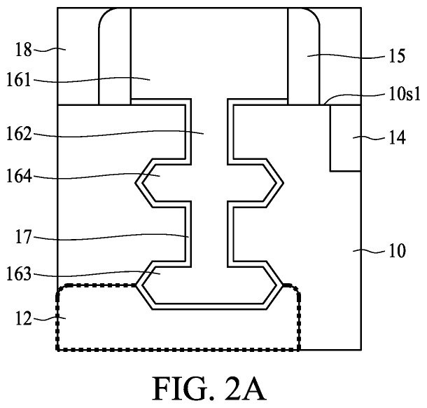

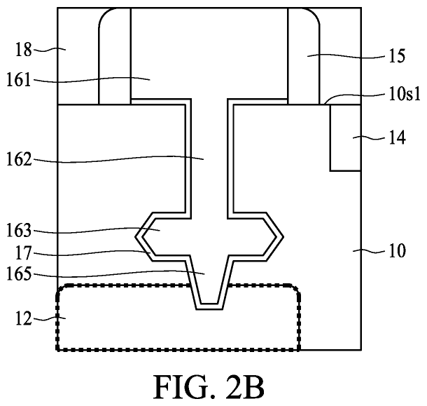

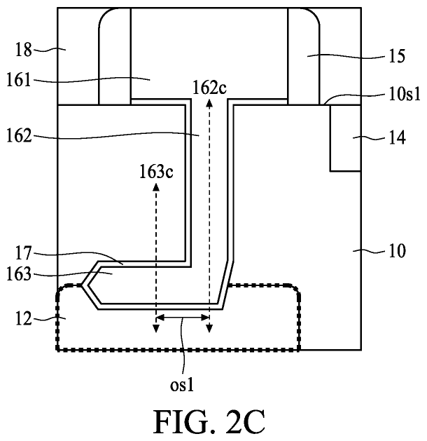

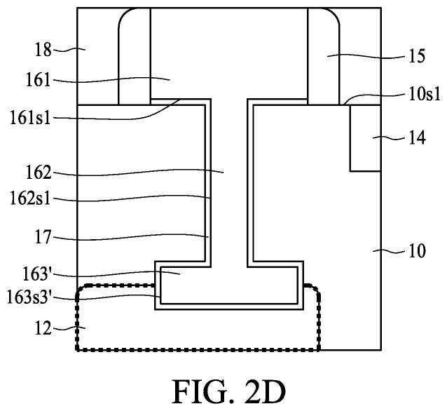

FIGS. 2A, 2B, 2C, and 2D each illustrate a schematic diagram of a portion of an image sensor, in accordance with some embodiments.

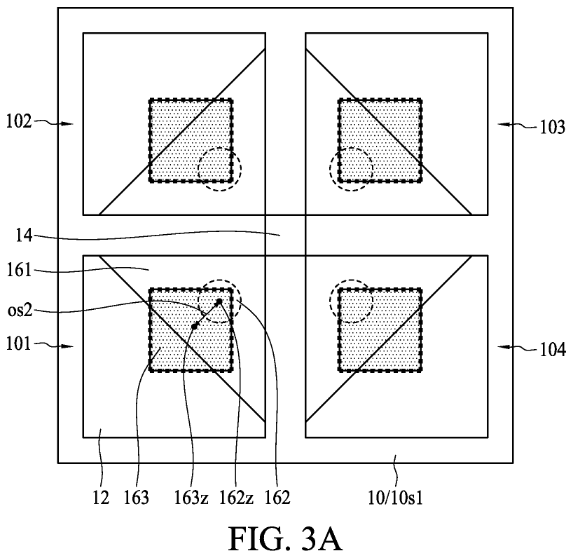

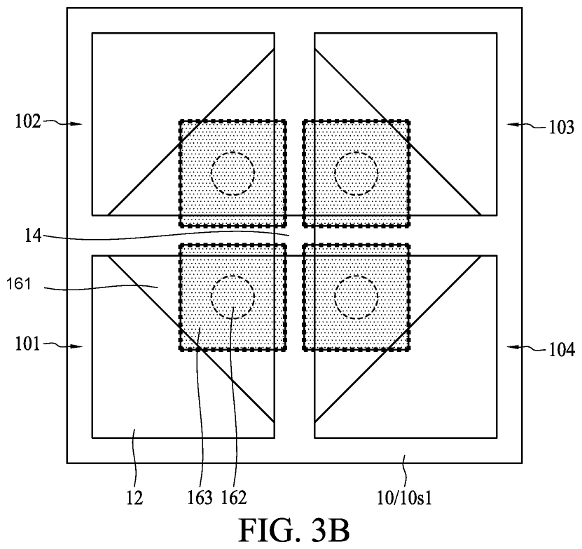

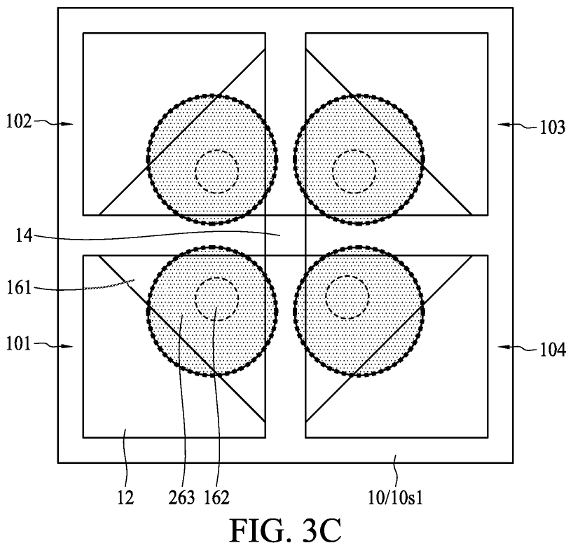

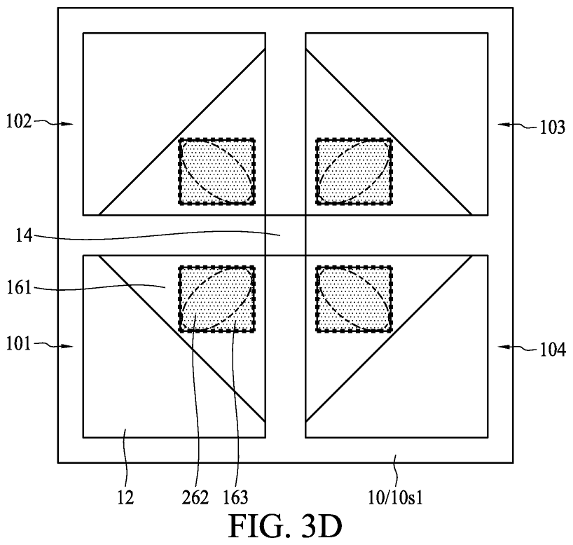

FIGS. 3A, 3B, 3C, and 3D each illustrate a schematic diagram of a top view of an image sensor, in accordance with some embodiments.

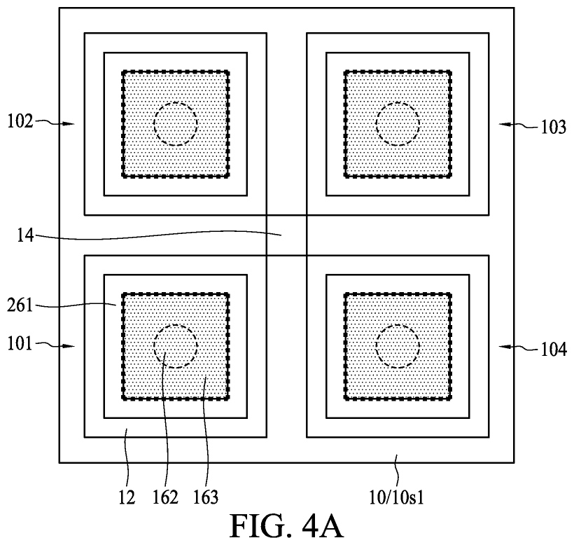

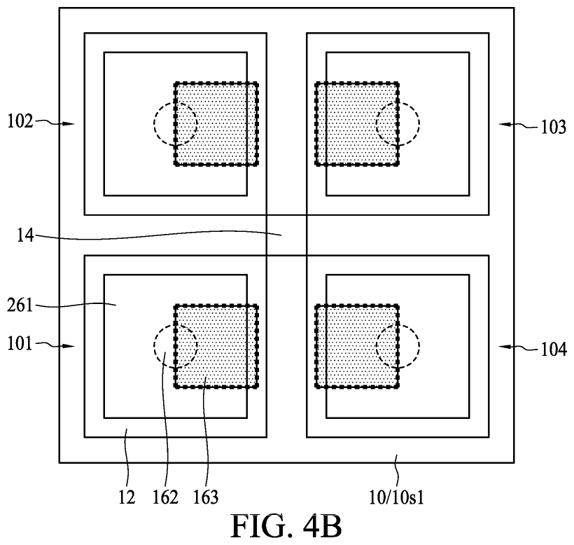

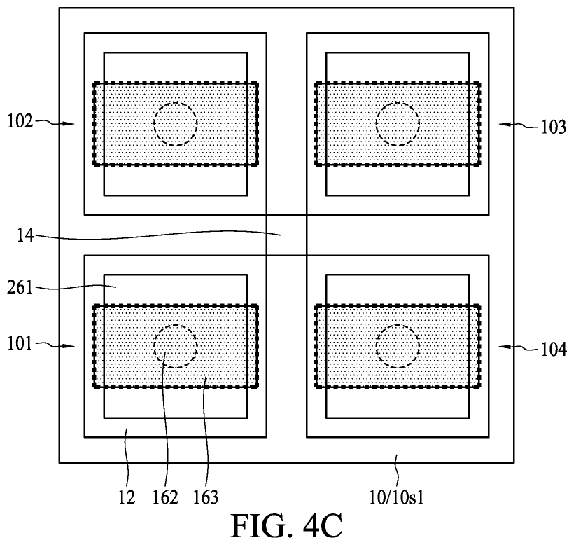

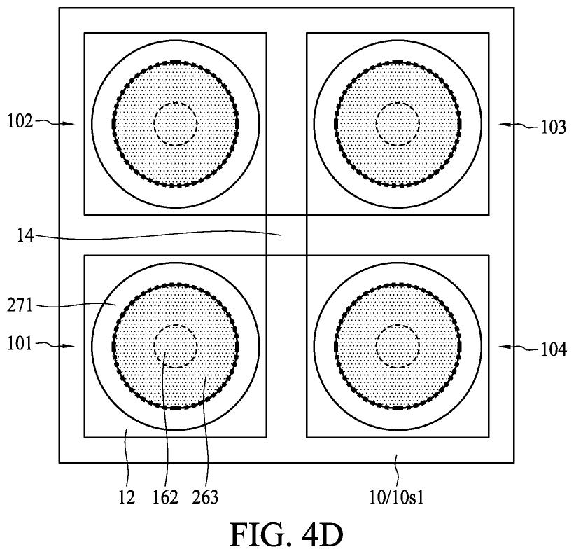

FIGS. 4A, 4B, 4C, and 4D each illustrate a schematic diagram of a top view of an image sensor, in accordance with some embodiments.

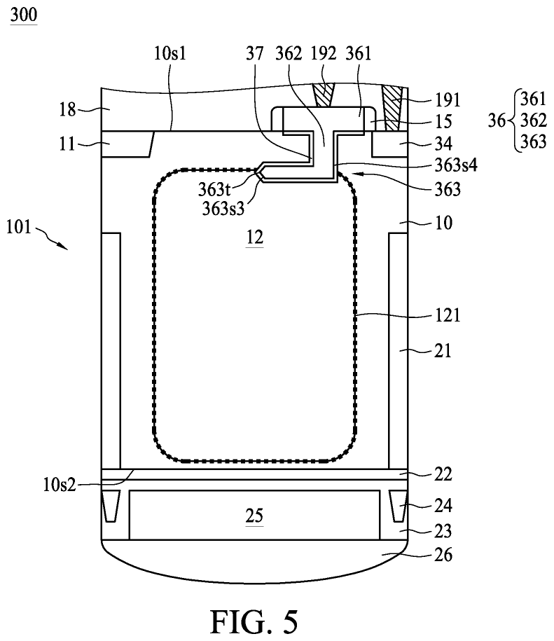

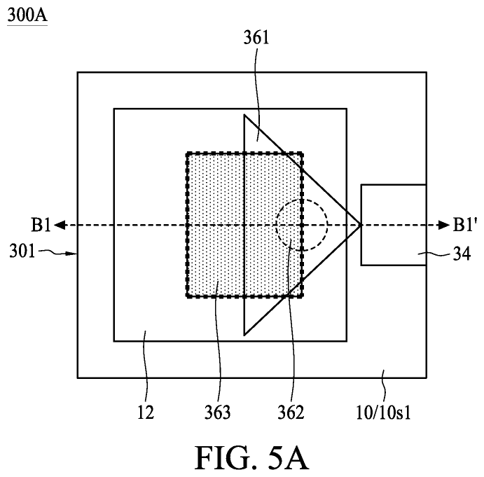

FIG. 5 illustrates a schematic diagram of a cross-sectional view of an image sensor, in accordance with some embodiments.

FIG. 5A illustrates a schematic diagram of a top view of an image sensor, in accordance with some embodiments.

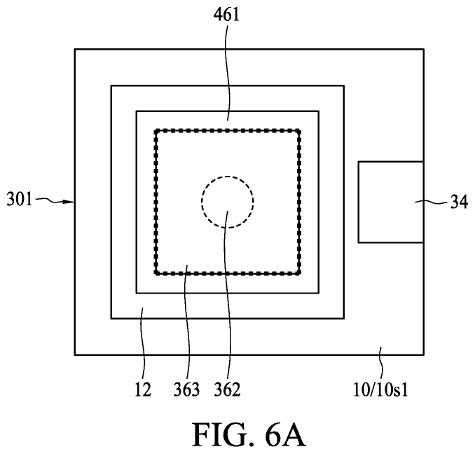

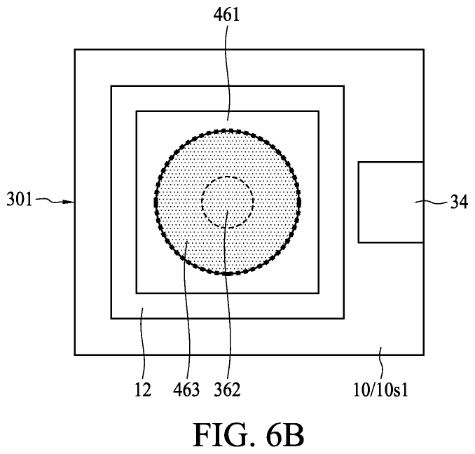

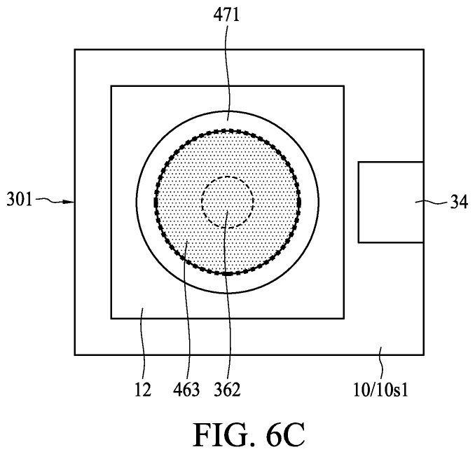

FIGS. 6A, 6B, and 6C each illustrate a schematic diagram of a top view of an image sensor, in accordance with some embodiments.

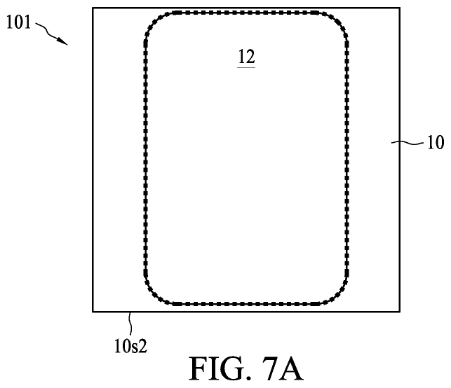

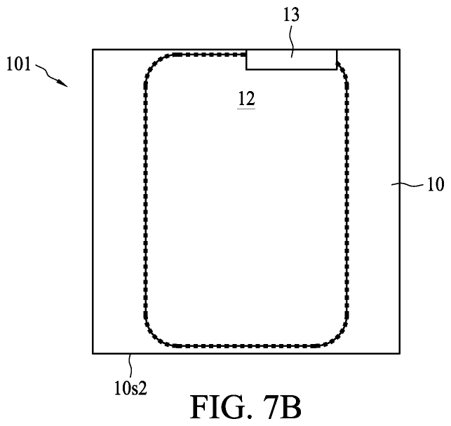

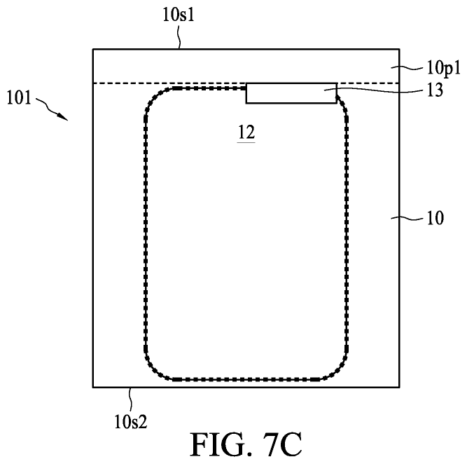

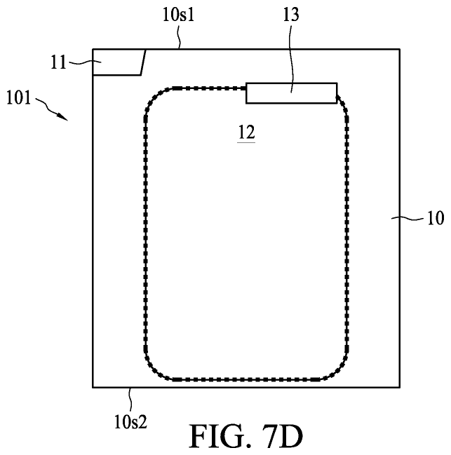

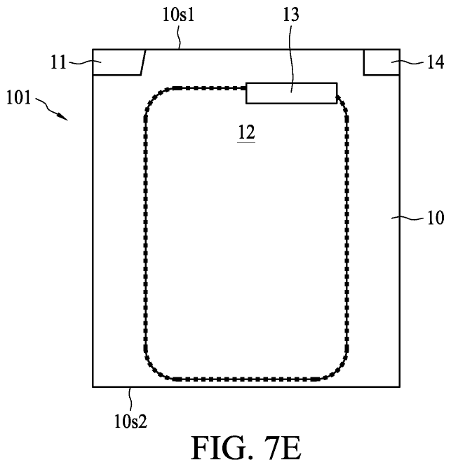

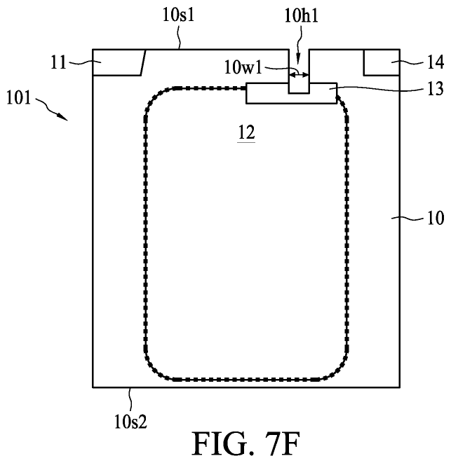

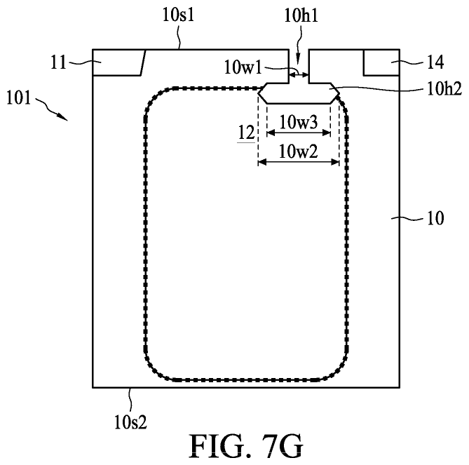

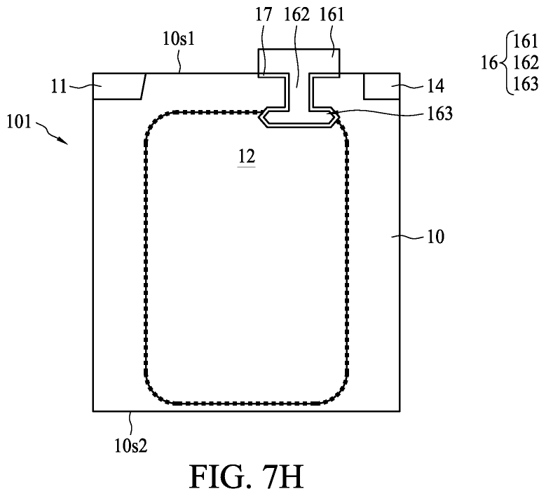

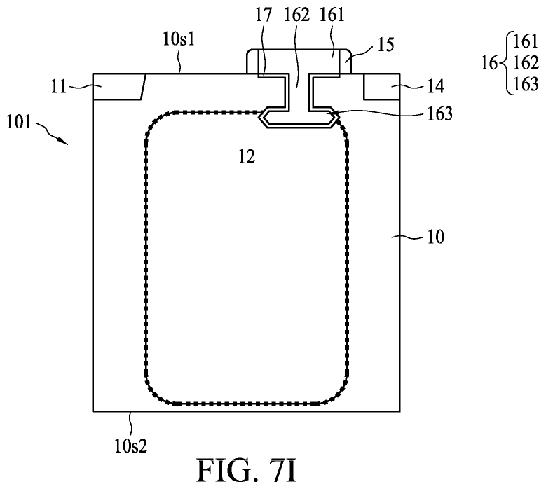

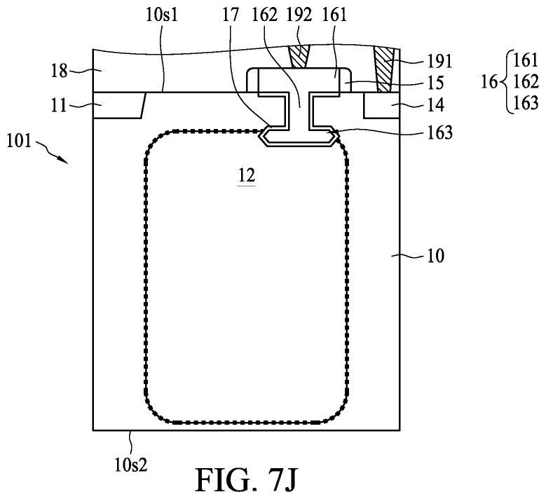

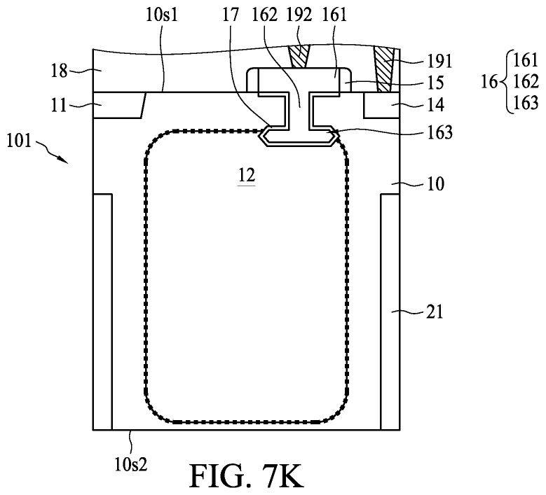

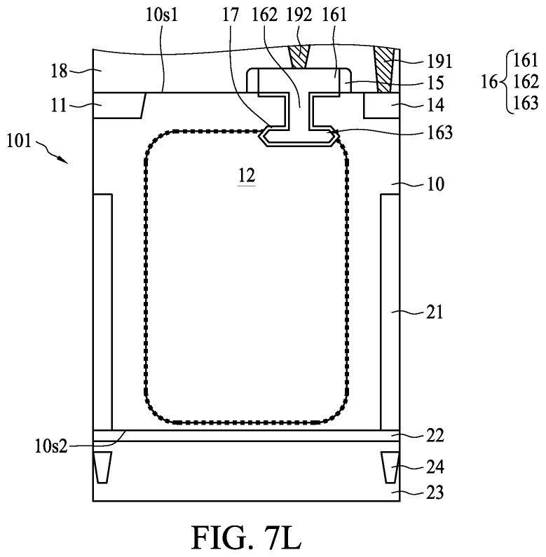

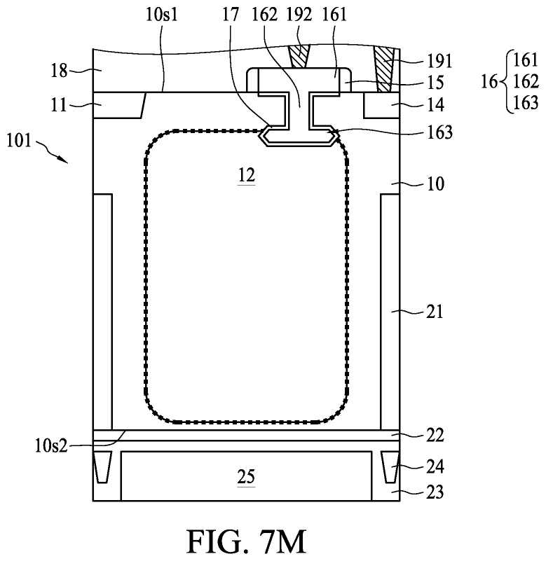

FIGS. 7A, 7B, 7C, 7D, 7E, 7F, 7G, 7H, 7I, 7J, 7K, 7L, and 7M illustrate a series of cross-sectional views of some embodiments of the image sensor of FIG. 1 at various stages of manufacture.

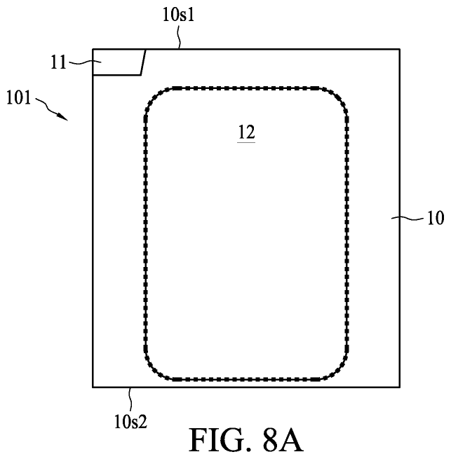

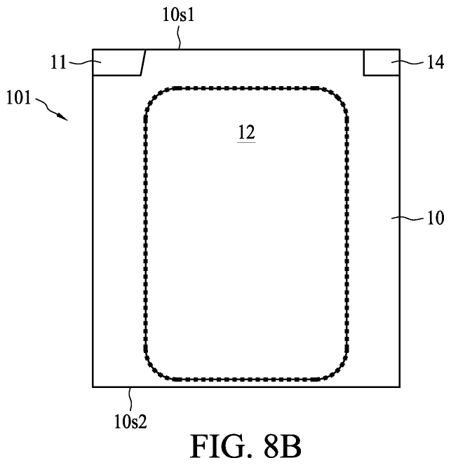

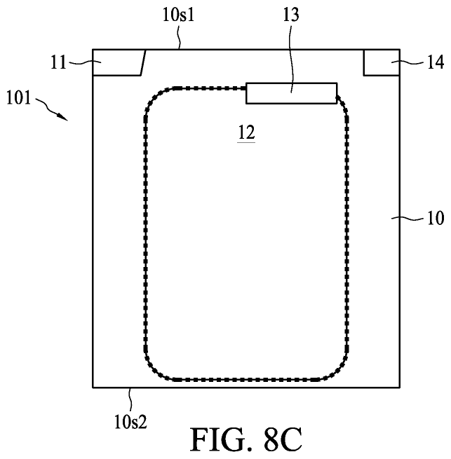

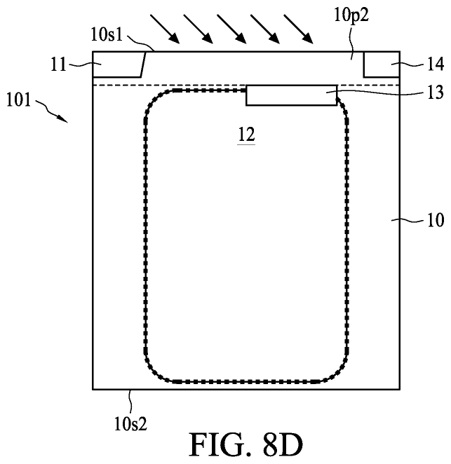

FIGS. 8A, 8B, 8C, and 8D illustrate a series of cross-sectional views of some embodiments of the image sensor of FIG. 1 at various stages of manufacture.

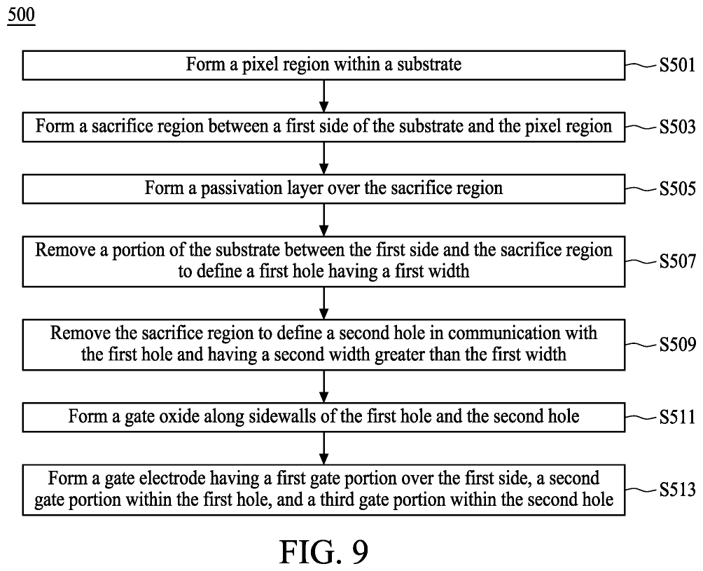

FIG. 9 illustrates a flowchart of some embodiments of a method of manufacturing an image sensor, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Embodiments, or examples, illustrated in the drawings are disclosed as follows using specific language. It will nevertheless be understood that the embodiments and examples are not intended to be limiting. Any alterations or modifications in the disclosed embodiments, and any further applications of the principles disclosed in this document are contemplated as would normally occur to one of ordinary skill in the pertinent art.

Further, it is understood that several processing steps and/or features of a device may be only briefly described. Also, additional processing steps and/or features can be added, and certain of the following processing steps and/or features can be removed or changed while still implementing the claims. Thus, it is understood that the following descriptions represent examples only and are not intended to suggest that one or more steps or features are required.

In addition, the present disclosure may repeat reference numerals and/or letters in the various examples. This repetition is for the purpose of simplicity and clarity and does not in itself dictate a relationship between the various embodiments and/or configurations discussed.

To improve the full-well capacity, an image sensor can be manufactured to have a deep photodiode region that is distant from the front-side of a substrate. The image sensor correspondingly has a gate that extends into a position between the deep photodiode region and a floating diffusion. The gate may form a channel region that transfers the photo-induced carriers from the deep photodiode region to the floating diffusion. Nevertheless, owing to the demand for increasingly higher pull-out speed of the image sensor, the design of the deep photodiode region and said gate may be no longer attractive.

The present disclosure relates to an image sensor comprising a deep photodiode region and a gate electrode including a planar transfer gate, a vertical transfer gate, and an embedded transfer gate. The planar transfer gate is outside a substrate, on a front-side of the substrate, and the embedded transfer gate is buried in the substrate. Further, the vertical transfer gate extends from the planar transfer gate to the embedded transfer gate.

The embedded transfer gate laterally extends within the substrate and has a width relatively larger than that of the vertical transfer gate. The embedded transfer gate may be formed by etching a sacrificial region and depositing a gate material therein. The embedded transfer gate is at least partially disposed within or adjacent to the deep photodiode region, thereby increasing the interface area between the gate electrode and the deep photodiode region. In other words, the channel region under the embedded transfer gate provides a larger pathway for the photo-induced carriers to be transferred to the floating node. The embedded transfer gate enhances the charge (or carrier) extraction from the deep photodiode region. Thus, the pull-out speed and the full-well capacity can be increased.

FIG. 1 illustrates a schematic diagram of a cross-sectional view of an image sensor 100, in accordance with some embodiments. The image sensor 100 has a pixel 101. The term “pixel” refers to a unit cell containing features (for example, a photodetector and various circuitries, which may include various semiconductor devices) for converting electromagnetic radiation to an electrical signal. Each pixel may include a photodetector, such as a photogate-type photodetector, for recording an intensity or brightness of light (radiation). Each pixel may also include various semiconductor devices, such as various transistors including a transfer transistor, a reset transistor, a source-follower transistor, a select transistor, another suitable transistor, or combinations thereof. Additional circuitry, input, and/or output may be coupled to the pixel array to provide an operating environment for the pixels and support external communications with the pixels. For example, the pixel array may be coupled with readout circuitry and/or control circuitry.

The image sensor 100 (or the pixel 101) includes a substrate 10, a shallow trench isolation (STI) structure 11, a pixel region 12, floating node 14, a spacer 15, a gate electrode 16, a gate oxide 17, an inter-level dielectric (ILD) layer 18, conductive contacts 191 and 192, a deep trench isolation (DTI) structure 21, an anti-reflection layer 22, a dielectric layer 23, a metal grid structure 24, a color filter 25, and a microlens 26.

The substrate 10 (or a semiconductor substrate) has a first side (or a front-side) 10s1 and a second side (or a back-side) 10s2 opposite to the first side 10s1. In some embodiments, the substrate 10 may comprise any type of semiconductor body (e.g., silicon/CMOS bulk, SiGe, SOI, etc.) such as a semiconductor wafer or one or more dies on a wafer, as well as any other type of semiconductor and/or epitaxial layers formed thereon and/or otherwise associated therewith. In some embodiments, the substrate 10 may have a depth in a range of from about 2 μm to about 10 μm.

The STI structure 11 is disposed proximate to the first side 10s1 of the substrate 10. The STI structure 11 may surround the pixel region 12 and the floating node 14. In some embodiments, the STI structure 11 may have a width in a range of from about 50 nm to about 200 nm. In some embodiments, the STI structure 11 may comprise, for example, oxide, nitride, high-k dielectric material such as aluminum oxide (AlO), tantalum oxide (TaO), hafnium oxide (HfO), hafnium silicon oxide (HfSiO), hafnium aluminum oxide (HfAlO), or hafnium tantalum oxide (HMO), or any combination thereof.

The pixel region 12 is disposed within the substrate 10. The substrate 10 has a second doping type (e.g., p-type doping) that is different than a first doping type (e.g., n-type doping) of the pixel region 12 and contacts the pixel region 12 to form a P-N junction photodiode 121. The P-N junction photodiode 121 is configured to convert radiation that enters the substrate 10 from the second side 10s2 into an electrical signal. When incident light (containing photons of sufficient energy) strikes the P-N junction photodiode 121, an electron-hole pair is created. If absorption occurs in the junction's depletion region, or one diffusion length away from it, the carriers (or photo-induced carriers) of this electron-hole pair are swept from the junction by the built-in electric field of the depletion region. The pixel region 12 may be formed by implantation into the substrate 10 with a first dopant (e.g., n-type dopant) opposite to a second dopant (e.g., p-type dopant of the substrate 10).

The floating node (or a floating diffusion region) 14 is disposed proximate to the first side 10s1 of the substrate 10. The floating node 14 is disposed aside of the pixel region 12 (or the P-N junction photodiode 121). The floating node 14 may be electrically connected to a source follower transistor and/or a select transistor (not shown) of the image sensor 100 via the conductive contact 191. The floating node 14 may be formed as a high implant (e.g., N+ implant) in the substrate 10. The floating node 14 may be configured to store the charges that are transferred and generated from the pixel region 12. The charges stored in the floating node 14 would then be converted into a voltage signal, which can be read or processed by the circuitry of the image sensor 100 (e.g., the source follower transistor and/or the select transistor).

The gate electrode (or a transfer gate electrode) 16 is disposed proximate to the first side 10s1 of the substrate 10. The gate electrode 16 may be disposed between the floating node 14 and the pixel region 12. The gate electrode 16 is configured to control the transfer of the charges generated in the pixel region 12. The gate oxide 17 is disposed along the surfaces of the gate electrode 16. The gate oxide 17 is disposed between the gate electrode 16 and the substrate 10. When a suitable voltage (e.g., a positive voltage or VDD) is applied onto the gate electrode 16 via the conductive contact 192, the gate electrode 16 will be turned on and a channel region will be generated along a portion of the substrate 10 that is adjacent to the gate oxide 17. During the operation, the photo-induced carriers (or electrons) in the pixel region 12 are transferred to the floating node 14 through the channel region under the gate electrode 16. If the potential of the floating node 14 is sufficiently high (e.g., the charges within the floating node 14 are sufficiently abundant), the circuitry of the image sensor 100 will be activated.

In some embodiments, the gate electrode 16 may be or comprise, for example, copper, aluminum copper, some other metal, doped polysilicon, doped germanium, or III-V material (e.g., GaAs, GaN), some other conductive material, or any combination of the foregoing. In some embodiments, the gate oxide 17 may be or comprise, for example, SiO₂, HfO₂, ZrO₂, Al₂O₃, La₂O₃, etc. In some embodiments, the gate oxide 17 may contain Nitride compound or Carbon compound.

The spacer 15 is disposed on the first side 10s1 of the substrate 10. The spacer 15 surrounds the gate electrode 16. The spacer 15 may partially and vertically overlap the floating node 14. In some embodiments, the spacer 15 may be or comprise, for example, SiO₂, Si₃N₄, or the like.

The ILD layer 18 is disposed on the first side 10s1 of the substrate 10. The ILD layer 18 covers the gate electrode 16 and the spacer 15. The ILD layer 18 surrounds the conductive contacts 191 and 192. The ILD layer 18 may comprise one or more of a low-k dielectric layer (e.g., a dielectric with a dielectric constant less than about 3.9), an ultra low-k dielectric layer, or an oxide (e.g., silicon oxide). The conductive contact 191 is in contact with the floating node 14 to form an ohmic contact therebetween. The conductive contact 192 is in contact with the gate electrode 16 to form an ohmic contact therebetween. In some embodiments, the conductive contacts 191 and 192 may comprise a conductive metal such as copper or tungsten, for example.

The DTI structure 21 is disposed within the substrate 10. The DTI structure 21 extends from the second side 10s2 of the substrate 10 to a position within the substrate 10. The DTI structure 21 surrounds the pixel region 12. The DTI structure 21 is used to optically isolate the pixel 101 from other adjacent pixels (e.g., the pixels 102, 103, and 104 in FIG. 1A). The DTI structure 21 may have a depth in a range of from about 2 μm to about 10 μm. In some embodiments, the DTI structure 21 comprises a dielectric fill layer (e.g., an oxide layer). In some embodiments, the DTI structure 21 may comprise, for example, oxide, nitride, high-k dielectric material such as aluminum oxide (AlO), tantalum oxide (TaO), hafnium oxide (HfO), hafnium silicon oxide (HfSiO), hafnium aluminum oxide (HfAlO), or hafnium tantalum oxide (HMO), or any combination thereof. In some embodiments, the substrate 10 may include a doped region (e.g., a p-type doped region) surrounding the DTI structure 21 to compensate for the damage incurred during formation of the DTI structure 21.

The anti-reflection layer 22 is disposed on the second side 10s2 of the substrate 10. The anti-reflection layer 22 is disposed between the substrate 10 and the color filter 25. The anti-reflection layer 22 may minimize light reflection and thus allow more light to reach the pixel region 12. In some embodiments, the anti-reflection layer 22 may comprise, for example, oxide, nitride, high-k dielectric material such as aluminum oxide (AlO), tantalum oxide (TaO), hafnium oxide (HfO), hafnium silicon oxide (HfSiO), hafnium aluminum oxide (HfAlO), or hafnium tantalum oxide (HMO), or any combination thereof.

The dielectric layer 23 is disposed on the anti-reflection layer 22. The dielectric layer 23 spaces the substrate 10 from the metal grid structure 24. The dielectric layer 23 may be, for example, an oxide, such as silicon dioxide.

The metal grid structure 24 is disposed on a portion of the dielectric layer 23. The metal grid structure 24 is surrounded by the dielectric layer 23. The metal grid structure 24 may be aligned with the DTI structure 21. The metal grid structure 24 is used to optically isolate the pixel 101 from other adjacent pixels (e.g., the pixels 102, 103, and 104 in FIG. 1A). The metal grid structure 24 may be, for example, tungsten, copper, or aluminum copper.

The color filter 25 is disposed on the dielectric layer 23. The color filter 25 is embedded in the dielectric layer 23. The color filter 25 is surrounded by the metal grid structure 24. The color filter 25 is aligned with the pixel region 12. Such a relationship can increase the illumination of the incident light on the pixel region 12. The color filter 25 is configured to transmit specific wavelengths of incident radiation or incident light. For example, the color filter 25 may be configured to transmit the incident radiation with wavelengths from 450 nm to 495 nm (e.g., blue light), from 495 nm to 570 nm (e.g., green light), from 620 nm to 750 nm (e.g., red light), or from 800 nm to 2500 nm (e.g., near infrared light).

The microlens 26 is disposed on the color filter 25. The microlens 26 is disposed on the dielectric layer 23. The microlens 26 has a curved surface (or convex surface) that facilitates the condensation of the incident light. The microlens 26 is aligned with the pixel region 12 and the color filter 25. Such a relationship can increase the illumination of the incident light on the pixel region 12.

In the back-side illumination (BSI), light is incident on the second side 10s2 of the substrate 10 via, in sequence, the microlens 26, the color filter 25, the dielectric layer 23, and the anti-reflection layer 22. The incident light then passes through the substrate 10 and reaches the pixel region 12. When incident light strikes the P-N junction photodiode 121 of the pixel region 12, multiple photo-induced carriers (e.g., electrons) are created. The P-N junction photodiode 121 collects the photo-induced carriers and, once the gate electrode 16 is turned on, the photo-induced carriers will be transferred from the pixel region 12 to the floating node 14. There may be unwanted refraction light or reflection light when the incident light passes through the interfaces. The metal grid structure 24 and the DTI structure 21 are used to reflect the unwanted refraction light or reflection light back to the pixel region 12, and thus full-well capacity of the image sensor 100 can be increased and the optical isolation among adjacent pixels can be improved (or the crosstalk can be reduced).

FIG. 1A illustrates a schematic diagram of a top view 100A of an image sensor (e.g., the image sensor 100), in accordance with some embodiments. The image sensor 100 further includes pixels 102, 103, 104. The pixels 102, 103, and 104 are adjacent to the pixel 101. The pixels 102, 103, and 104 may have a structure similar to that of the pixel 101. The pixels 102, 103, and 104 may each include a gate electrode and a pixel region similar to those depicted in FIG. 1. The pixels 101, 102, 103, and 104 may have a size from 0.5 μm to 10 μm. The pixels 101, 102, 103, and 104 may be surrounded by the STI structure 11 illustrated in FIG. 1. The pixels 101, 102, 103, and 104 share the floating node 14.

Each gate electrode 16 of the pixels 101, 102, 103, and 104 is disposed close to the floating node 14. The gate electrode 16 includes a first gate portion 161, a second gate portion 162, and a third gate portion 163 that overlap with each other in the top view 100A. The layout of the second gate portion 162 and the third gate portion 163 are asymmetric within the pixels; both are located closer to the floating node 14. In order to avoid any impact on the electrical characteristics of the floating node 14, the floating node 14 is free from overlap with the third gate portion 163 in the top view 100A. The first gate portion 161 may have a triangular shape in the top view 100A. The second gate portion 162 is depicted with a dashed line to indicate that the second gate portion 162 is disposed below the first gate portion 161. The second portion 162 may have a circular shape in the top view 100A. The third gate portion 163 is depicted with a dotted line to indicate that the third gate portion 163 is disposed below the second gate portion 162. The third gate portion 163 may have a rectangular shape in the top view 100A.

FIG. 1 may be a cross-sectional view along the line A1-A1′ in FIG. 1A. Referring back to FIG. 1, the first gate portion 161 is connected to the second gate portion 162. The second gate portion 162 is connected to the third gate portion 163. The first gate portion 161 is disposed over the first side 10s1 of the substrate 10. The second gate portion 162 is disposed within the substrate 10. The third gate portion 163 is disposed below the second gate portion 162. The spacer 15 surrounds and/or contacts the first gate portion 161 and is spaced apart from the second gate portion 162 and the third gate portion 163. The second gate portion 162 is at a position vertically between the first gate portion 161 and the third gate portion 163. The third gate portion 163 is at a first elevation different from a second elevation of the first gate portion 161. In other words, the horizontal level of the third gate portion 163 is different from the horizontal level of the first gate portion 161.

The STI structure 11 is closer to the first side 10s1 than the third gate portion 163. In other words, the bottom surface of the STI structure 11 is closer to the first side 10s1 than to a top surface (e.g., the second surface 163s2 in FIG. 1B) of the third gate portion 163. The gate oxide 17 is disposed below the first gate portion 161. The gate oxide 17 surrounds the second gate portion 162 and the third gate portion 163. Two of the first gate portion 161, the second gate portion 162, and the third gate portion 163 may have no interface therebetween. The first gate portion 161 may be continuous with the second gate portion 162. The second gate portion 162 may be continuous with the third gate portion 163.

FIG. 1B illustrates a schematic diagram of an enlarged view of a box B1 in FIG. 1. The first gate portion 161 has a bottom surface 161s1 facing the first side 10s1 of the substrate 10. The gate oxide 17 is disposed along the bottom surface 161s1 of the first gate portion 161. The second gate portion 162 has a sidewall surface 162s1. The gate oxide 17 surrounds the sidewall surface 162s1 of the second gate portion 162. The third gate portion 163 has a first surface (or a bottom surface) 163s1, and a second surface (or a top surface) 163s2 opposite to the first surface 163s1. The first surface 163s1 and the second surface 163s2 are both substantially parallel to and spaced apart from the first side 10s1 of the substrate 10. The third gate portion 163 has a sidewall surface 163s3 connected to the first surface 163s1 and the second surface 163s2 of the third gate portion 163. The gate oxide 17 is disposed along the first surface 163s1, the second surface 163s2, and the sidewall surface 163s3 of the third gate portion 163. The third gate portion 163 has a tip 163t distant from the first surface 163s1 and the second surface 163s2 of the third gate portion 163. The tip 163t may be formed by a lower portion of the sidewall surface 163s3 and an upper portion of the sidewall surface 163s3. The lower portion and the upper portion of the sidewall surface 163s3 extend in different directions. The third gate portion 163 may have a diamond-shaped profile owing to the crystal orientation, e.g., (110) of the substrate 10 and the lateral etching to form a hole which is then filled (entirely or partially) to form the third gate portion 163. The lateral etching is selective to the (111) crystallographic plane (or surface) of the substrate 10. The lateral etching exposes the (111) surface, which are the lower portion and the upper portion of the sidewall surface 163s3.

In crystalline semiconductor materials, the atoms which make up the solid are arranged in a periodic fashion. If the periodic arrangement exists throughout the solid, the substance is formed of a crystal. The periodic arrangement of atoms in a crystal is commonly called “the crystal lattice.” The crystal lattice also contains a volume which is representative of the entire lattice and is referred to as a unit cell that is regularly repeated throughout the crystal. For example, silicon has a diamond cubic lattice structure, which can be represented as two interpenetrating face-centered cubic lattices. Thus, analysis and visualization of cubic lattices can be extended to the characterization of silicon crystals. In the description herein, references to various planes in semiconductor crystals (e.g., silicon crystals) will be made, especially to the (100), (110), and (111) planes. These planes show the orientation of the plane of semiconductor atoms relative to the principle crystalline axes. The numbers (xyz) are referred to as Miller indices and are determined from the reciprocals of the points at which the crystal plane of silicon intersects the principal crystalline axes. In some embodiments, the third gate portion 163 may have different profiles based on different crystal orientations, e.g., (100), (111), and so on.

The first gate portion 161 has a first width 161w in a direction parallel to the first side 10s1 of the substrate 10. The second gate portion 162 has a second width 162w in a direction parallel to the first side 10s1 of the substrate 10. The second width 162w may be in a range from 50-90 nm, or around 70 nm. The second gate portion 162 may have a tapered profile toward the pixel region 12. The third gate portion 163 has a third width 163w1 formed by the tip 163t in a direction parallel to the first side 10s1 of the substrate 10. The third gate portion 163 further has a fourth width 163w2 formed by the first surface 163s1. The first width 161w of the first gate portion 161 is greater than the second width 162w of the second gate portion 162. In some embodiments, the first width 161w is greater than the third width 163w1. In some embodiments, the first width 161w is smaller than the third width 163w1. In some embodiments, the first width 161w is substantially the same as the third width 163w1. The third width 163w1 of the third gate portion 163 is greater than the second width 162w. The fourth width 163w2 is less than the third width 163w1. With relatively wide first and third portions 161 and 163 and the relatively narrow second portion 162 therebetween, the gate electrode 16 may have a 90-degree rotated “H” shaped profile. A height (or a thickness) 162h of the second gate portion 162 is higher than a height (or a thickness) 163h of the third gate portion 163. The second portion 162 and the third portion 163 may form a mallet shaped profile. The height 162h of the second gate portion 162 may be from 400 nm to 600 nm. The height 163h of the third gate portion 163 may be from 60 nm to 100 nm, or from 10 nm to 1 μm.

Since the pixel region 12 is an implant region, the location of the boundary thereof depends on the thermal budget, the doping concentration and the dopant of the pixel region 12 and the surrounding area of the substrate 10. The positional relationship between the pixel region 12 and the third gate portion 163 may be varied. In some embodiments, the third gate portion 163 may be partially embedded in the pixel region 12. The first surface 163s1 of the third gate portion 163 is located within the pixel region 12. In some embodiments, the third gate portion 163 may be completely embedded in the pixel region 12. The first surface 163s1 and the second surface 163s2 of the third gate portion 163 may be located within the pixel region 12. In some embodiments, the third gate portion 163 may be disposed outside the pixel region 12. The first surface 163s1 and the second surface 163s2 of the third gate portion 163 may be located outside the pixel region 12.

Each of the first gate portion 161 (e.g., a planar transfer gate), the second gate portion 162 (e.g., a vertical transfer gate), and the third gate portion 163 (e.g., an embedded transfer gate) is configured to transfer photon-induced carriers from the pixel region 12 to the floating node 14. The embedded transfer gate 163 laterally extends within the substrate 10 and has the third width 163w1 which is relatively larger than the second width 162w of the vertical transfer gate 162. The embedded transfer gate 163 may be formed by etching a sacrificial region (e.g., the sacrificial region 13 in FIG. 7B) and depositing a gate material therein. The embedded transfer gate 163 is close to or at least partially disposed within or adjacent to the pixel region 12, thereby increasing the interface area between the gate electrode 16 and the pixel region 12. When the gate electrode 16 is turned on, the channel region under the embedded transfer gate 163 provides a larger pathway for the photo-induced carriers to be transferred from the pixel region 12 to the floating node 14. The embedded transfer gate 163 enhances the charge (or carrier) extraction from the pixel region 12. Thus, the pull-out speed and the full-well capacity can be increased.

FIG. 1B-1 illustrates a schematic diagram of a three-dimensional view of a gate electrode (e.g., the gate electrode 16, in accordance with some embodiments). The first gate portion 161, the second gate portion 162, and the third gate portion 163 may have substantially circular shapes with different diameters. The third gate portion 163 may have a diamond-shaped profile. FIG. 1B-1 illustrates two sidewall faces. In some embodiments, the diamond-shaped profile of the third gate portion 163 may have more than two sidewall faces.

FIG. 1C illustrates a schematic diagram of another enlarged view of a box B1 in FIG. 1. The enlarged view of FIG. 1C is similar to the enlarged view of FIG. 1B. Therefore, some detailed descriptions may refer to corresponding preceding paragraphs and are not repeated hereinafter for conciseness, with differences therebetween as follows.

In some embodiments, the second gate portion has a void (or a second void) 201 extending substantially perpendicular to the first side 10s1 of the substrate 10. The third gate portion 163 has a void (or a first void) 202 extending substantially parallel to the first side 10s1 of the substrate 10. The first void 202 is in communication with the second void 201. A middle part of the first void 202 may be in communication with an end of the second void 201. The first void 202 and the second void 201 may form a “T” shaped profile. In some embodiments, the first void 202 may be spaced apart from the second void 201. The first void 202 and the second void 201 may be filled with air.

The first void 202 and the second void 201 may be formed during the formation of the gate electrode 16 through, e.g., a chemical vapor deposition. Owing to the precursor flow, step coverage, nucleation and growth of the deposited gate material, the first void 202 and the second void 201 may have different sizes and profiles. The first void 202 and the second void 201 may each have an oblate ellipsoid shape. Since the second gate portion 162 has relatively small width, less precursor can enter into a deeper hole (e.g., the second hole 10h2 in FIG. 7G), which is then deposited with the gate material to form the third gate portion 163. The diameter of the first void 202 may be larger than that of the second void 201.

The voids may influence the electrical characteristics of the gate electrode. The size of the voids can be minimized by controlling the deposition of the gate material.

FIG. 2A illustrates a schematic diagram of a portion of an image sensor (e.g., the image sensor 100), in accordance with some embodiments. The portion of the image sensor of FIG. 2A is similar to the enlarged view of FIG. 1B. Therefore, some detailed descriptions may refer to corresponding preceding paragraphs and are not repeated hereinafter for conciseness, with differences therebetween as follows.

The gate electrode 16 further includes a fourth gate portion 164 disposed between the first gate portion 161 and the third gate portion 163. The fourth gate portion 164 intersects the second gate portion 162. The fourth gate portion 164 may have a similar structure to that of the third gate portion 163. For example, the fourth gate portion 164 may have a diamond-shaped profile. The fourth gate portion 164 (or a further embedded transfer gate) is configured to transfer photon-induced carriers from the pixel region 12 to the floating node 14. The further embedded transfer gate 164 laterally extends within the substrate 10 and has a width relatively larger than the width of the vertical transfer gate 162. The further embedded transfer gate 164 may be formed by etching a sacrificial region and depositing a gate material therein. When the gate electrode 16 is turned on, the channel region under the further embedded transfer gate 164 provides a further larger pathway for the photo-induced carriers to be transferred from the pixel region 12 to the floating node 14. The further embedded transfer gate 164 enhances the charge (or carrier) extraction from the pixel region 12. Thus, the pull-out speed and the full-well capacity can be increased. In some embodiments, the gate electrode 16 may include more than two embedded transfer gates.

FIG. 2B illustrates a schematic diagram of a portion of an image sensor (e.g., the image sensor 100), in accordance with some embodiments. The portion of the image sensor of FIG. 2B is similar to the enlarged view of FIG. 1B. Therefore, some detailed descriptions may refer to corresponding preceding paragraphs and are not repeated hereinafter for conciseness, with differences therebetween as follows.

The third gate portion 163 is disposed closer to the first side 10s1 of the substrate 10, as compared to the third gate portion 163 in FIG. 1B. The gate electrode 16 further includes a fifth gate portion 165 disposed below the third gate portion 163. The fifth gate portion 165 may have a tapered profile toward the pixel region 12. The fifth gate portion 165 may be partially embedded in or outside the pixel region 12, depending on the boundary of the pixel region 12. The third gate portion 163 in FIG. 2B is distant from the pixel region 12. The damage incurred during formation (e.g., etching) of the third gate portion 163 would not influence the optical-electrical characteristics of the pixel region 12.

FIG. 2C each illustrates a schematic diagram of a portion of an image sensor (e.g., the image sensor 100), in accordance with some embodiments. The portion of the image sensor of FIG. 2C is similar to the enlarged view of FIG. 1B. Therefore, some detailed descriptions may refer to corresponding preceding paragraphs and are not repeated hereinafter for conciseness, with differences therebetween as follows.

A central line 162c of the second gate portion 162 extends substantially perpendicular to the first side 10s1 of the substrate 10, and a central line 163c of the third gate portion 163 extends substantially perpendicular to the first side 10s1 of the substrate 10. The central line 162c of the second gate portion 162 is misaligned with the central line 163c of the third gate portion 163 with an offset os1.

FIG. 2D illustrates a schematic diagram of a portion of an image sensor (e.g., the image sensor 100), in accordance with some embodiments. The portion of the image sensor of FIG. 2D is similar to the enlarged view of FIG. 1B. Therefore, some detailed descriptions may refer to corresponding preceding paragraphs and are not repeated hereinafter for conciseness, with differences therebetween as follows.

The gate electrode 16 includes a gate portion 163′, rather than the third gate portion 163 in FIG. 1B. The gate portion 163′ has a substantially rectangular shape, owing to the crystal orientation of the substrate 10. The gate portion 163′ has a sidewall surface 163s3′ substantially perpendicular to the first side 10s1 of the substrate 10.

FIG. 3A illustrates a schematic diagram of a top view of an image sensor, in accordance with some embodiments. The top view of FIG. 3A is similar to the top view 100A of FIG. 1A. Therefore, some detailed descriptions may refer to corresponding preceding paragraphs and are not repeated hereinafter for conciseness, with differences therebetween as follows.

A center 162z of the second gate portion 162 is misaligned with a central line 163z of the third gate portion 163 with an offset os2. The second gate portion 162 partially overlaps the third gate portion 163 in the top view. The third gate portion 163 is farther away from the floating node 14 than the second gate portion 162 in the top view. As such, the potential of the third gate portion 163 would not influence the floating node 14.

FIG. 3B illustrates a schematic diagram of a top view of an image sensor, in accordance with some embodiments. The top view of FIG. 3B is similar to the top view 100A of FIG. 1A. Therefore, some detailed descriptions may refer to corresponding preceding paragraphs and are not repeated hereinafter for conciseness, with differences therebetween as follows.

As shown in FIG. 3B, at least a portion of the third gate portion 163 overlaps the floating node 14 in the top view. The width of the third gate portion 163 is larger than that in FIG. 1A.

FIG. 3C illustrates a schematic diagram of a top view of an image sensor, in accordance with some embodiments. The top view of FIG. 3C is similar to the top view 100A of FIG. 1A. Therefore, some detailed descriptions may refer to corresponding preceding paragraphs and are not repeated hereinafter for conciseness, with differences therebetween as follows. The gate electrode 16 has a gate portion 263, rather than the third gate portion 163 in FIG. 1A. The gate portion 263 may have a circular shape in the top view.

FIG. 3D illustrates a schematic diagram of a top view of an image sensor, in accordance with some embodiments. The top view of FIG. 3D is similar to the top view 100A of FIG. 1A. Therefore, some detailed descriptions may refer to corresponding preceding paragraphs and are not repeated hereinafter for conciseness, with differences therebetween as follows. The gate electrode 16 has a gate portion 262, rather than the second gate portion 162 in FIG. 1A. The gate portion 262 may have an elliptical shape in the top view.

FIG. 4A illustrates a schematic diagram of a top view of an image sensor, in accordance with some embodiments. The top view of FIG. 4A is similar to the top view 100A of FIG. 1A. Therefore, some detailed descriptions may refer to corresponding preceding paragraphs and are not repeated hereinafter for conciseness, with differences therebetween as follows.

The layouts of the second gate portion 162 and the third gate portion 163 are symmetric within the pixels; both are aligned with the pixel region 12. The gate electrode 16 includes a gate portion 261, rather than the first gate portion 161 in FIG. 1A. The gate portion 261 may have a substantially rectangular shape in the top view. The gate portion 261 is aligned with the second gate portion 162 and the third gate portion 163.

FIG. 4B illustrates a schematic diagram of a top view of an image sensor, in accordance with some embodiments. The top view of FIG. 4B is similar to the top view of FIG. 4A. Therefore, some detailed descriptions may refer to corresponding preceding paragraphs and are not repeated hereinafter for conciseness, with differences therebetween as follows.

The second gate portion 162 is misaligned with the third gate portion 163. The second gate portion 162 partially overlaps the third gate portion 163 in the top view. At least a portion of the third gate portion 163 is free from overlapping the gate portion 261 in the top view.

FIG. 4C illustrates a schematic diagram of a top view of an image sensor, in accordance with some embodiments. The top view of FIG. 4C is similar to the top view of FIG. 4A. Therefore, some detailed descriptions may refer to corresponding preceding paragraphs and are not repeated hereinafter for conciseness, with differences therebetween as follows.

The third gate portion 163 is wider than the gate portion 261. At least a portion of the third gate portion 163 is free from overlapping the gate portion 261 in the top view.

FIG. 4D illustrates a schematic diagram of a top view of an image sensor, in accordance with some embodiments. The top view of FIG. 4D is similar to the top view of FIG. 4A. Therefore, some detailed descriptions may refer to corresponding preceding paragraphs and are not repeated hereinafter for conciseness, with differences therebetween as follows.

The gate electrode 16 includes a gate portion 271, rather than the first gate portion 261 in FIG. 4A. The gate portion 271 may have a circular shape in the top view. The gate electrode 16 has a gate portion 263, rather than the third gate portion 163 in FIG. 4A. The gate portion 263 may have a circular shape in the top view.

FIG. 5 illustrates a schematic diagram of a cross-sectional view of an image sensor 300, in accordance with some embodiments. The image sensor 300 of FIG. 5 is similar to the image sensor 100 of FIG. 1. Therefore, some detailed descriptions may refer to corresponding preceding paragraphs and are not repeated hereinafter for conciseness, with differences therebetween as follows.

The image sensor 300 has a pixel 301 which is a single pixel having its own dedicated floating node 34. The floating node (or a floating diffusion region) 34 is disposed proximate to the first side 10s1 of the substrate 10. The floating node 34 is disposed aside of the pixel region 12 (or the P-N junction photodiode 121). The floating node 34 may be electrically connected to a source follower transistor and/or a select transistor (not shown) of the image sensor 100 via the conductive contact 191. The floating node 34 may be formed as a high implant (e.g., N+ implant) in the substrate 10. The floating node 34 may be configured to store the charges that are transferred and generated from the pixel region 12. The charges stored in the floating node 34 would then be converted into a voltage signal, which can be read or processed by the circuitry of the image sensor 300 (e.g., the source follower transistor and/or the select transistor).

The image sensor 300 may include a gate electrode 36, rather than the gate electrode 16 of the image sensor 100. The gate electrode 36 may be disposed between the floating node 34 and the pixel region 12. The gate electrode 36 is configured to control the transfer of the charges generated in the pixel region 12. The gate oxide 37 is disposed along the surfaces of the gate electrode 36. The gate oxide 37 is disposed between the gate electrode 36 and the substrate 10. When a suitable voltage (e.g., a positive voltage or VDD) is applied onto the gate electrode 36 via the conductive contact 192, the gate electrode 36 will be turned on and a channel region will be generated along a portion of the substrate 10 that is adjacent to the gate oxide 37. During the operation, the photo-induced carriers (or electrons) in the pixel region 12 are transferred to the floating node 34 through the channel region under the gate electrode 36. If the potential of the floating node 34 is sufficiently high (e.g., the charges within the floating node 34 is sufficiently abundant), the circuitry of the image sensor 300 will be activated.

In some embodiments, the gate electrode 36 may be or comprise, for example, copper, aluminum copper, some other metal, doped polysilicon, doped germanium, or III-V material (e.g., GaAs, GaN), some other conductive material, or any combination of the foregoing. In some embodiments, the gate oxide 37 may be or comprise, for example, SiO₂, HfO₂, ZrO₂, Al₂O₃, La₂O₃, etc. In some embodiments, the gate oxide 37 may contain Nitride compound or Carbon compound.

The spacer 15 is disposed on the first side 10s1 of the substrate 10. The spacer 15 surrounds the gate electrode 36. The spacer 15 may partially and vertically overlap the floating node 34. In some embodiments, the spacer 15 may be or comprise, for example, SiO₂, Si₃N₄, or the like.

The conductive contact 191 is in contact with the floating node 34 to form an ohmic contact therebetween. The conductive contact 192 is in contact with the gate electrode 36 to form an ohmic contact therebetween.

FIG. 5A illustrates a schematic diagram of a top view 300A of an image sensor (e.g., the image sensor 300), in accordance with some embodiments. The gate electrode 36 of the pixel 301 is disposed close to the floating node 34. The gate electrode 36 includes a first gate portion 361, a second gate portion 362, and a third gate portion 363 overlapping (e.g., partially overlapping) with each other in the top view 300A. The layouts of the second gate portion 362 and the third gate portion 363 are asymmetric within the pixel 301; both are located closer to the floating node 34. In order to avoid any impact on the electrical characteristics of the floating node 34, the floating node 34 is free from overlapping with the third gate portion 363 in the top view 300A. The first gate portion 361 may have a triangular shape in the top view 300A. The second gate portion 362 is depicted with a dashed line to indicate that the second gate portion 362 is disposed below the first gate portion 361. The second gate portion 362 may have a circular shape in the top view 300A. The third gate portion 363 is depicted with a dotted line to indicate that the third gate portion 363 is disposed below the second gate portion 362. The third gate portion 363 may have a rectangular shape in the top view 300A.

FIG. 5 may be a cross-sectional view along the line B1-B1′ in FIG. 5A. Referring back to FIG. 5, the first gate portion 361 is connected to the second gate portion 362. The second gate portion 362 is connected to the third gate portion 363. The first gate portion 361 is disposed over the first side 10s1 of the substrate 10. The second gate portion 362 is disposed within the substrate 10. The second gate portion 362 may have a tapered profile toward the pixel region 12. The third gate portion 363 is disposed below the second gate portion 362. The spacer 15 surrounds and/or contacts the first gate portion 361 and is spaced apart from the second gate portion 362 and the third gate portion 363. The second gate portion 362 is at a position vertically between the first gate portion 361 and the third gate portion 363. The third gate portion 363 is at a first elevation different from a second elevation of the first gate portion 361. In other words, the horizontal level of the third gate portion 363 is different from the horizontal level of the first gate portion 361.

The STI structure 11 is closer to the first side 10s1 than the third gate portion 363. In other words, the bottom surface of the STI structure 11 is closer to the first side 10s1 than to a top surface of the third gate portion 363. The gate oxide 37 is disposed below the first gate portion 361. The gate oxide 37 surrounds the second gate portion 362 and the third gate portion 363. Two of the first gate portion 361, the second gate portion 362, and the third gate portion 363 may have no interface therebetween. The first gate portion 361 may be continuous with the second gate portion 362. The second gate portion 362 may be continuous with the third gate portion 363.

The third gate portion 363 may be misaligned with the second gate portion 362. The third gate portion 363 may have a half-diamond profile. A sidewall surface 363s3 of the third gate portion 363 distant from the second gate portion 362 has two portions that extend in different directions and form a tip 363t. The tip 363t is distant from a bottom surface and a top surface of the third gate portion 363. A sidewall surface 363s4 of the third gate portion 363 proximate to the second gate portion 362 may have a substantially flat shape.

Since the pixel region 12 is an implant region, the location of the boundary thereof depends on the thermal budget, the doping concentration and the dopant of the pixel region 12 and the surrounding area of the substrate 10. The positional relationship between the pixel region 12 and the third gate portion 363 may be varied. In some embodiments, the third gate portion 363 may be partially embedded in the pixel region 12. In some embodiments, the third gate portion 363 may be completely embedded in the pixel region 12. In some embodiments, the third gate portion 363 may be disposed outside the pixel region 12.

Each of the first gate portion 361 (e.g., a planar transfer gate), the second gate portion 362 (e.g., a vertical transfer gate), and the third gate portion 363 (e.g., an embedded transfer gate) is configured to transfer photon-induced carriers from the pixel region 12 to the floating node 34. The embedded transfer gate 363 laterally extends within the substrate 10 and is wider than the vertical transfer gate 362. The embedded transfer gate 363 may be formed by etching a sacrificial region (e.g., the sacrificial region 13 in FIG. 7B) and depositing a gate material therein. The embedded transfer gate 363 is close to or at least partially disposed within or adjacent to the pixel region 12, thereby increasing the interface area between the gate electrode 36 and the pixel region 12. When the gate electrode 36 is turned on, the channel region under the embedded transfer gate 363 provides a larger pathway for the photo-induced carriers to be transferred from the pixel region 12 to the floating node 34. The embedded transfer gate 363 enhances the charge (or carrier) extraction from the pixel region 12. Thus, the pull-out speed and the full-well capacity can be increased.

FIG. 6A illustrates a schematic diagram of a top view of an image sensor, in accordance with some embodiments. The top view of FIG. 6A is similar to the top view 300A of FIG. 5A. Therefore, some detailed descriptions may refer to corresponding preceding paragraphs and are not repeated hereinafter for conciseness, with differences therebetween as follows.

The layouts of the second gate portion 362 and the third gate portion 363 are symmetric within the pixels; both are aligned with the pixel region 12. The gate electrode 36 includes a gate portion 461, rather than the first gate portion 361 in FIG. 5A. The gate portion 461 may have a substantially rectangular shape in the top view. The gate portion 461 is aligned with the second gate portion 362 and the third gate portion 363.

FIG. 6B illustrates a schematic diagram of a top view of an image sensor, in accordance with some embodiments. The top view of FIG. 6B is similar to the top view 300A of FIG. 5A. Therefore, some detailed descriptions may refer to corresponding preceding paragraphs and are not repeated hereinafter for conciseness, with differences therebetween as follows. The gate electrode 36 has a gate portion 463, rather than the third gate portion 363 in FIG. 6A. The gate portion 463 may have a circular shape in the top view.

FIG. 6C illustrates a schematic diagram of a top view of an image sensor, in accordance with some embodiments. The top view of FIG. 6C is similar to the top view 300A of FIG. 5A. Therefore, some detailed descriptions may refer to corresponding preceding paragraphs and are not repeated hereinafter for conciseness, with differences therebetween as follows. The gate electrode 16 includes a gate portion 471, rather than the first gate portion 361 in FIG. 5A. The gate portion 471 may have a circular shape in the top view. The gate electrode 36 has a gate portion 463, rather than the third gate portion 363 in FIG. 5A. The gate portion 463 may have a circular shape in the top view.

FIGS. 7A, 7B, 7C, 7D, 7E, 7F, 7G, 7H, 7I, 7J, 7K, 7L, and 7M illustrate a series of cross-sectional views of some embodiments of the image sensor 100 of FIG. 1 at various stages of manufacture.

In FIG. 7A, a substrate 10 is provided. A pixel region (or a deep photodiode region) 12 is formed within the substrate 10. The pixel region 12 may be formed by implantation into the substrate 10 with a first dopant (e.g., n-type dopant) opposite to a second dopant (e.g., p-type dopant of the substrate 10).

In FIG. 7B, a sacrificial region 13 is formed within the substrate 10. The sacrificial region 13 may be formed by implantation into the substrate with a doping concentration relatively higher than that of the pixel region 12 and the substrate 10. The dopant of the sacrificial region 13 may be an n-type dopant.

In FIG. 7C, a passivation layer 10p1 is formed over the sacrificial region 13. The passivation layer 10p1 may be an epitaxial layer. The passivation layer 10p1 may be a p-type layer that passivates the damage induced by the implantation of the sacrificial region 13. There may be no boundary between the passivation layer 10p1 and the substrate 10. The passivation layer 10p1 may be referred to as a part of the substrate 10, and thus the dashed line therebetween may be an imaginary line.

In FIG. 7D, an STI structure 11 is formed proximate to the first side 10s1 of the substrate 10. The STI structure 11 may be formed by removing a portion of the substrate 10 to form a recess and depositing a dielectric material into the recess. The STI structure 11 may be closer to the first side 10s1 of the substrate 10 than the sacrificial region 13.

In FIG. 7E, a floating node 14 is formed proximate to the first side 10s1 of the substrate 10. The floating node 14 may be formed as a high implant (e.g., N+ implant) in the substrate 10. The floating node 14 is distant from the pixel region 12.

In FIG. 7F, a portion of the substrate 10 between the first side 10s1 and the sacrificial region 13 is removed to form a first hole 10h1 having a first width 10w1. In some embodiments, a portion of the sacrificial region may be removed. The first width 10w1 may be in a range from 50-90 nm, or around 70 nm. The first hole 10h1 may be tapered toward the pixel region 12.

In FIG. 7G, the sacrificial region 13 is removed to form a second hole 10h2 in communication with the first hole 10h1 and having a second width 10w2. The second hole 10h2 is below the first hole 10h1. The second hole 10h2 extends laterally in the substrate 10. The second hole 10h2 may be formed by laterally etching the sacrificial region 13. Since the doping concentration of the sacrificial region 13 is quite different from that of the substrate 10 and the pixel region 12, the etchant will selectively etch the sacrificial region 13 with minimum damage to the surrounding area. As such, the second width 10w2 of the second hole 10h2 is greater than the first width 10w1 of the first hole 10h1. In some embodiments, the etchant may be or comprise a chlorine-based etchant and/or some other suitable etchant type. The second hole 10h2 may have a diamond profile owing to the lateral etching on the substrate 10 having the crystal orientation (110). The lateral etching is selective to the (111) crystallographic plane (or surface) of the substrate 10. The lateral etching exposes the (111) surface, which are lateral surfaces of the second hole 10h2. The second hole 10h2 may have a third width 10w3 formed by a bottom side of the second hole 10h2.

In FIG. 7H, a gate oxide 17 is formed along sidewalls of the first hole 10h1 and the second hole 10h2. The gate oxide 17 may be formed along a portion of the first side 10s1 of the substrate 10. Prior to the formation of the gate oxide 17, a passivation layer or treatment may be performed on the sidewalls of the first hole 10h1 and the second hole 10h2, to alleviate the damage of the removal of the portion of the substrate 10 and the sacrificial region 13.

In FIG. 7H, a gate electrode 16, having a first gate portion 161 over the first side 10s1 of the substrate 10, a second gate portion 162 within the first hole 10h1, and a third gate portion 163 within the second hole 10h2, is formed. The third gate portion 163 may have a diamond profile inherited from the second hole 10h2.

In FIG. 7I, a spacer 15 is formed to surround the first gate portion 161 of the gate electrode 16. The spacer 15 is spaced apart from the second gate portion 162 and the third gate portion 163.

In FIG. 7J, an ILD layer 18 is formed over the first side 10s1 of the substrate 10. A conductive contact 191 is formed over the floating node 14 to make an electrical connection therebetween. A conductive contact 192 is formed over the gate electrode 16 to make an electrical connection therebetween. The conductive contacts 191 and 192 may be formed by etching the ILD layer 18 to form holes and depositing conductive material therein. The ILD layer 18 may comprise one or more of a low-k dielectric layer (e.g., a dielectric with a dielectric constant less than about 3.9), an ultra low-k dielectric layer, or an oxide (e.g., silicon oxide). In some embodiments, the conductive contacts 191 and 192 may comprise a conductive metal such as copper or tungsten, for example.

In FIG. 7K, a DTI structure 21 is formed within the substrate 10. The DTI structure 21 extends from the second side 10s2 of the substrate 10 to a position within the substrate 10. The DTI structure 21 may be formed by removing a portion of the substrate 10 to form a deep trench and depositing a dielectric material into the deep trench. The DTI structure 21 surrounds the pixel region 12 to prevent the cross-talk from adjacent pixels.

In FIG. 7L, an anti-reflection layer 22 is formed on the second side 10s2 of the substrate 10 to minimize the reflection and thus allow more light to reach the pixel region 12. In some embodiments, the anti-reflection layer 22 may comprise, for example, oxide, nitride, high-k dielectric material such as aluminum oxide (AlO), tantalum oxide (TaO), hafnium oxide (HfO), hafnium silicon oxide (HfSiO), hafnium aluminum oxide (HfAlO), or hafnium tantalum oxide (HMO), or any combination thereof.

In FIG. 7L, a dielectric layer 23 is formed on the anti-reflection layer 22. The dielectric layer 23 may be, for example, an oxide, such as silicon dioxide.

In FIG. 7L, a metal grid structure 24 is formed on a portion of the dielectric layer 23. The metal grid structure 24 is surrounded by the dielectric layer 23. The metal grid structure 24 is formed to align with the DTI structure 21. The metal grid structure 24 is used to optically isolate the pixel 101 from other adjacent pixels. The metal grid structure 24 may be, for example, tungsten, copper, or aluminum copper.

In FIG. 7M, a color filter 25 is formed on the dielectric layer 23. The color filter 25 is embedded in the dielectric layer 23. The color filter 25 may be formed by etching a portion of the dielectric layer 23 to form a recess and depositing organic dye or pigment-based materials into the recess. Afterwards, a microlens 26 may be formed on the color filter 25 and the dielectric layer 23 to form the image sensor 100 of FIG. 1.

FIGS. 8A, 8B, 8C, and 8D illustrate a series of cross-sectional views of some embodiments of the image sensor 100 of FIG. 1 at various stages of manufacture.

In FIG. 8A, a substrate 10 is provided. A pixel region (or a deep photodiode region) 12 is formed within the substrate 10. The pixel region 12 may be formed by implantation into the substrate 10 with a first dopant (e.g., n-type dopant) opposite to a second dopant (e.g., p-type dopant of the substrate 10). An STI structure 11 is formed proximate to the first side 10s1 of the substrate 10. The STI structure 11 may be formed by removing a portion of the substrate 10 to form a recess and depositing a dielectric material into the recess.

In FIG. 8B, a floating node 14 is formed proximate to the first side 10s1 of the substrate 10. The floating node 14 may be formed as a high implant (e.g., N+ implant) in the substrate 10. The floating node 14 is distant from the pixel region 12.

In FIG. 8C, a sacrificial region 13 is formed between the first side 10s1 of the substrate 10 and the pixel region 12. The sacrificial region 13 may be formed by implantation into the substrate with a doping concentration relatively higher than that of the pixel region 12 and the substrate 10. The dopant of the sacrificial region 13 may be an n-type dopant. The STI structure 11 may be closer to the first side 10s1 of the substrate 10 than the sacrificial region 13.

In FIG. 8D, a passivation layer 10p2 is formed over the sacrificial region 13 by implantation with a p-type dopant. The passivation layer 10p2 passivates the damage induced by the implantation of the sacrificial region 13. There may be no boundary between the passivation layer 10p2 and the substrate 10. The passivation layer 10p2 may be referred to as a part of the substrate 10, and thus the line therebetween may be an imaginary line.

The stages of FIGS. 7F-7M may follow the stages of FIGS. 8A, 8B, 8C, and 8D to form the image sensor 100 of FIG. 1.

FIG. 9 is a flowchart showing a method 500 of manufacturing an image sensor (e.g., the image sensor 100, 300), in accordance with some embodiments. The method 500 includes operations S501, S503, S505, S507, S509, S511, and S513. The sequence of the operations S501, S503, S505, S507, S509, S511, and S513 may be exemplary and will not delimit the present disclosure.

The method 500 begins with operation S501 including forming a pixel region (e.g., the pixel region 12) within a substrate (e.g., the substrate 10). Operation S501 may include implanting the substrate with a first dopant to form the pixel region, wherein the first dopant is different from a second dopant of the substrate 10.

In operation S503, the method 500 includes forming a sacrificial region (e.g., the sacrificial region 13) between a first side (e.g., the first side 10s1) of the substrate and the pixel region. Operation 503 may include implanting the substrate with a high doping concentration (e.g., N+ implant) to form the sacrificial region.

In operation S505, the method 500 includes forming a passivation layer (e.g., the passivation layer 10p1, 10p2) over the sacrificial region. Operation 503 may include depositing an epitaxial layer over the sacrificial region to form the passivation layer. In some embodiments, operation 503 may include implanting a portion of the substrate proximate the first side 10s1 to form the passivation layer. The passivation layer may be a p-type layer.

In operation S507, the method 500 includes removing a portion of the substrate between the first side and the sacrificial region to form a first hole (e.g., the first hole 10h1) having a first width (e.g., the first width 10w1).

In operation S509, the method 500 includes removing the sacrificial region to form a second hole (e.g., the second hole 10h2) in communication with the first hole and having a second width (e.g., the second width 10w2) greater than the first width. Operation S509 may include laterally etching the sacrificial region to form the second hole. Since the doping concentration of the sacrificial region 13 is quite different from that of the substrate 10 and the pixel region 12, the etchant will selectively etch the sacrificial region 13 with minimum damage to the surrounding area.

In operation S511, the method 500 includes forming a gate oxide (e.g., the gate oxide 17) along sidewalls of the first hole and the second hole. Operation S511 may include performing a passivation treatment along the sidewalls of the first hole and the second hole to alleviate the damage induced by the removal of the portion of the substrate and the sacrificial region.

In operation S513, the method 500 includes forming a gate electrode (e.g., the gate electrode 16, 36) having a first gate portion (e.g., the first gate portion or planar transfer gate 161, 361) over the first side, a second gate portion (e.g., the second gate portion or the vertical transfer gate 162, 362) within the first hole, and a third gate portion (e.g., the third gate portion or the embedded transfer gate 163, 363) within the second hole.

The embedded transfer gate laterally extends within the substrate and has a width relatively larger than that of the vertical transfer gate. The embedded transfer gate is at least partially disposed within or adjacent to the pixel region, thereby increasing the interface area between the gate electrode and the pixel region. In other words, the channel region under the embedded transfer gate provides a larger pathway for the photo-induced carriers to be transferred to the floating node. The embedded transfer gate enhances the charge (or carrier) extraction from the pixel region. Thus, the pull-out speed and the full-well capacity can be increased.

The method 500 is merely an example and is not intended to limit the present disclosure beyond what is explicitly recited in the claims. Additional operations can be provided before, during, or after each operation of the method 500, and some operations described can be replaced, eliminated, or reordered for additional embodiments of the method. In some embodiments, the method 500 can include further operations not depicted in FIG. 9. In some embodiments, the method 500 can include one or more operations depicted in FIG. 9.

According to other embodiments, an image sensor is provided. The image sensor includes a substrate and a gate electrode. The gate electrode is disposed proximate to a first side of the substrate. The gate electrode includes a first gate portion, a second gate portion, and a third gate portion. The first gate portion is disposed on the first side of the substrate. The second gate portion is disposed in the substrate and connected to the first gate portion. The third gate portion is disposed below and connected to the second gate portion. A first width of the first gate portion is greater than a second width of the second gate portion, and a third width of the third gate portion is greater than the second width.

According to other embodiments, an image sensor is provided. The image sensor includes a substrate and a gate portion. The substrate has a first side. The gate portion is disposed within the substrate and has a first surface and a second surface, both of which are substantially parallel to the first side of the substrate. The first surface and the second surface of the gate portion are spaced apart from the first side of the substrate.

According to other embodiments, a method of manufacturing an image sensor is provided, including: forming a pixel region in a substrate; forming a sacrificial region between a first side of the substrate and the pixel region; removing a portion of the substrate between the first side and the sacrificial region to form a first hole having a first width; removing the sacrificial region to form a second hole in communication with the first hole and having a second width greater than the first width; and forming a gate electrode having a first gate portion on the first side, a second gate portion in the first hole, and a third gate portion in the second hole.

The methods and features of the present disclosure have been sufficiently described in the above examples and descriptions. It should be understood that any modifications or changes without departing from the spirit of the present disclosure are intended to be covered in the protection scope of the present disclosure.

Moreover, the scope of the present application is not intended to be limited to the particular embodiments of the process, machine, manufacture, and composition of matter, means, methods and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein, may be utilized according to the present disclosure.

Accordingly, the appended claims are intended to include within their scope: processes, machines, manufacture, compositions of matter, means, methods or steps. In addition, each claim constitutes a separate embodiment, and any combination of various claims and embodiments are within the scope of the present disclosure.

What is claimed is:

1. An image sensor, comprising:
a substrate; and
a gate electrode disposed proximate to a first side of the substrate, comprising:
a first gate portion disposed on the first side of the substrate;
a second gate portion disposed in the substrate and connected to the first gate portion; and
a third gate portion disposed below and connected to the second gate portion,
wherein a first width of the first gate portion is greater than a second width of the second gate portion, and a third width of the third gate portion is greater than the second width.

2. The image sensor of claim 1, further comprising a pixel region disposed within the substrate, wherein the third gate portion has a first surface located within the pixel region.

3. The image sensor of claim 2, wherein the third gate portion is partially embedded in the pixel region.

4. The image sensor of claim 1, wherein the third gate portion is at a first elevation different from a second elevation of the first gate portion.

5. The image sensor of claim 1, further comprising a spacer surrounding the first gate portion and spaced apart from the second gate portion and the third gate portion.

6. The image sensor of claim 1, wherein the third gate portion has a first surface with a fourth width, and the fourth width is less than the third width of the third gate portion.

7. The image sensor of claim 6, wherein the third gate portion has a diamond-shaped profile.

8. The image sensor of claim 6, further comprising a gate oxide disposed along a sidewall surface and the first surface of the third gate portion.

9. The image sensor of claim 1, wherein the third gate portion has a first void extending substantially parallel to the first side of the substrate.

10. The image sensor of claim 9, wherein the second gate portion has a second void extending substantially perpendicular to the first side of the substrate and in communication with the first void.

11. The image sensor of claim 1, wherein the first gate portion, the second gate portion, and the third gate portion overlap with each other in a top view.

12. The image sensor of claim 1, wherein a central line of the second gate portion extends substantially perpendicular to the first side of the substrate, and a central line of the third gate portion extends substantially perpendicular to the first side of the substrate, and wherein the central line of the second gate portion is misaligned with the central line of the third gate portion with an offset.

13. The image sensor of claim 1, further comprising a floating node proximate to the first side of the substrate, wherein the floating node is free from overlapping with the third gate portion in a top view.

14. An image sensor, comprising:
a substrate having a first side; and
a gate electrode comprising a gate portion, which is buried in the substrate,
wherein the gate portion has a first surface and a second surface, which face opposite directions as each other and are both substantially parallel to the first side of the substrate, and
wherein the first surface and the second surface of the gate portion are spaced apart from the first side of the substrate.

15. The image sensor of claim 14, wherein the gate portion has a tip distant from the first surface and the second surface.

16. The image sensor of claim 14, further comprising:
a pixel region within the substrate; and
a floating node proximate to the first side of the substrate, wherein the gate portion is configured to transfer photon-induced carriers from the pixel region to the floating node.

17. The image sensor of claim 14, further comprising a shallow trench isolation (STI) structure proximate to the first side of the substrate, wherein the STI structure is closer to the first side than the gate portion.

18. A method of manufacturing an image sensor, comprising:
forming a pixel region in a substrate;
forming a sacrificial region between a first side of the substrate and the pixel region;
removing a portion of the substrate between the first side and the sacrificial region to form a first hole having a first width;
removing the sacrificial region to form a second hole in communication with the first hole and having a second width greater than the first width; and
forming a gate electrode having a first gate portion on the first side, a second gate portion in the first hole, and a third gate portion in the second hole.

19. The method of claim 18, further comprising forming a passivation layer over the sacrificial region.

20. The method of claim 18, further comprising forming a gate oxide along sidewalls of the first hole and the second hole.
